(19) United States
(12) Patent Application Publication
(10) Pub. No.: US 2013/0146128 A1
(43) Pub. Date: Jun. 13, 2013

(54) SOLAR CELL MODULE

(71) Applicants: Jung-Yup Yang, Yongin-si (KR); Yong-Hee Park, Yongin-si (KR); Seung-Hee Lee, Yongin-si (KR); Pil-Ho Huh, Yongin-si (KR); Young-Kyoung Ahn, Yongin-si (KR); Dong-Jun Lee, Yongin-si (KR); Bum-Rae Kim, Yongin-si (KR)

(72) Inventors: Jung-Yup Yang, Yongin-si (KR); Yong-Hee Park, Yongin-si (KR); Seung-Hee Lee, Yongin-si (KR); Pil-Ho Huh, Yongin-si (KR); Young-Kyoung Ahn, Yongin-si (KR); Dong-Jun Lee, Yongin-si (KR); Bum-Rae Kim, Yongin-si (KR)

(21) Appl. No.: 13/586,162

(22) Filed: Aug. 15, 2012

(30) Foreign Application Priority Data
Dec. 13, 2011 (KR) 10-2011-0133992

(51) Int. Cl. H01L 31/05; H01L 31/048

(52) U.S. Cl. 136/251

(57) ABSTRACT

A solar cell module includes solar cell strings including a plurality of solar cells, and conductive patterns for electrically coupling respective ones of the plurality of solar cells to each other, a first sealing film and a front substrate on the solar cell strings, and a second sealing film and a back substrate under the solar cell strings, wherein each of the plurality of solar cells includes bus bars on a back surface of a respective one of the solar cells, a plurality of finger lines protruding from the bus bars in a direction substantially perpendicular to the bus bars, and an insulating layer for covering the plurality of finger lines, wherein the conductive patterns are arranged in parallel along a length direction of the bus bars, overlap with the bus bars, and have a width greater than the a width of the bus bars.

### CROSS-REFERENCE TO RELATED APPLICATION

This application claims priority to and the benefit of Korean Patent Application No. 10-2011-0133992, filed on Dec. 13, 2011, in the Korean Intellectual Property Office, the disclosure of which is incorporated herein in its entirety by reference.

### BACKGROUND

1. Field

One or more embodiments of the present invention relate to a solar cell module.

2. Description of Related Art

Currently, depletion of existing energy resources, such as oil or coal, is expected, and thus interests in alternative sources of energy are increased. From among them, solar cells for transforming solar energy into electric energy by using semiconductor elements are regarded as next-generation energy sources.

Solar cells refer to devices for transforming optical energy into electric energy by using a photovoltaic effect, and may be classified according to their materials as, for example, silicon solar cells, thin film solar cells, dye-sensitized solar cells, and organic polymer solar cells. From among them, silicon solar cells are mainly featured. In solar cells, it is very important to increase transformation efficiency related to a ratio of transforming incident sunlight into electric energy. In this regard, conventional silicon solar cells employ a back-contact solar cell structure for disposing a front surface electrode on a back surface of a substrate.

A solar cell module has a structure in which a plurality of solar cells for generating photovoltaic power are coupled in series or parallel, and the solar cells may be electrically coupled by conductive patterns such as ribbons. However, if the solar cells are bonded to the ribbons, a resistance may be increased, and thus an output of the solar cell module may be reduced.

### SUMMARY

One or more embodiments of the present invention include a solar cell module capable of reducing or minimizing a resistance generated when a plurality of solar cells are coupled by conductive patterns.

One or more embodiments of the present invention include a solar cell module capable of lowering required alignment accuracy between solar cells and conductive patterns, thus increasing a manufacturing yield of the solar cell module.

Additional aspects will be set forth in part in the description which follows and, in part, will be apparent from the description, or may be learned by practice of the presented embodiments of the present invention.

According to one or more embodiments of the present invention, a solar cell module includes solar cell strings including a plurality of solar cells, and conductive patterns for electrically coupling respective ones of the plurality of solar cells to each other, a first sealing film and a front substrate on the solar cell strings, and a second sealing film and a back substrate under the solar cell strings, wherein each of the plurality of solar cells includes bus bars on a back surface of a respective one of the solar cells, a plurality of finger lines protruding from the bus bars in a direction substantially perpendicular to the bus bars, and an insulating layer for covering the plurality of finger lines, wherein the conductive patterns are arranged in parallel along a length direction of the bus bars, overlap with the bus bars, and have a width greater than the a width of the bus bars.

Portions of the conductive patterns may be on the insulating layer.

Each of the plurality of solar cells may include a substrate including a silicon semiconductor having a first conductive type, an emitter diffusion region on a back surface of the substrate and having a second conductive type opposite to the first conductive type, and a back surface field region on the back surface of the substrate and having the first conductive type.

An upper surface of the substrate may include an uneven structure.

The solar cell module may further include a front surface field layer and an anti-reflective layer on an upper surface of the substrate.

The bus bars may include first through fourth bus bars arranged in parallel and spaced apart from each other, the first and third bus bars may be electrically coupled to the emitter diffusion region, and the second and fourth bus bars may be electrically coupled to the back surface field region.

The third bus bar may be between the second and fourth bus bars, and the second bus bar may be between the first and third bus bars.

The insulating layer may be between the bus bars.

The first and third bus bars may be electrically coupled to each other, and the second and fourth bus bars may be electrically coupled to each other.

The conductive patterns may be on the first and fourth bus bars.

The conductive patterns may include metal.

The solar cell module may further include a conductive film between the conductive patterns and the bus bars.

The solar cell module may further include an insulating film between at least one of the solar cells and the second sealing film.

The conductive patterns may be on the insulating film.

According to one or more embodiments of the present invention, a solar cell module includes solar cell strings including a plurality of solar cells electrically coupled by conductive patterns, wherein each of the solar cells includes bus bars on a back surface of a respective one of the solar cells, a plurality of finger lines protruding from the bus bars in a direction substantially perpendicular to the bus bars, and an insulating layer for covering the plurality of finger lines and being level with the bus bars, and wherein the conductive patterns are arranged in parallel along a length direction of the bus bars and are coupled to the bus bars and portions of the insulating layer outside the bus bars.

Each of the plurality of solar cells may include a substrate including a silicon semiconductor, and an emitter diffusion region and a back surface field region on a back surface of the substrate, the emitter diffusion region and the back surface field region may have opposite conductive types, the bus bars may include first through fourth bus bars arranged in parallel and spaced apart from each other, and the first and third bus bars may be electrically coupled to the emitter diffusion region, the second and fourth bus bars may be electrically coupled to the back surface field region, and the first and third bus bars may be arranged alternately with the second and fourth bus bars.

The conductive patterns may respectively electrically couple the first and third bus bars of one of the solar cells to the fourth and second bus bars of a neighboring one of the solar cells.

The first and third bus bars may be electrically coupled to each other, and the second and fourth bus bars may be electrically coupled to each other.

The conductive patterns may electrically couple the first bus bar of one of the solar cells to the fourth bus bar in a neighboring one of the solar cells.

A ratio of a width of the conductive patterns to a width of the bus bars may be greater than 1 and less than 50.

### BRIEF DESCRIPTION OF THE DRAWINGS

These and/or other aspects will become apparent and more readily appreciated from the following description of embodiments of the present invention, taken in conjunction with the accompanying drawings, of which:

FIG. 1 is an exploded perspective view of a solar cell module according to an embodiment of the present invention;

FIG. 2 is a diagram showing a solar cell of the solar cell module of the embodiment illustrated in FIG. 1, according to an embodiment of the present invention;

FIG. 3 is a cross-sectional view taken along the line I-I′ of the solar cell illustrated in FIG. 2;

FIG. 4 is a diagram for describing a method of forming solar cell strings of the solar cell module of the embodiment illustrated in FIG. 1, according to an embodiment of the present invention;

FIG. 5 is a cross-sectional view taken along the line II-II′ illustrated in FIG. 4;

FIG. 6 is a plan view of solar cells of the solar cell module of the embodiment illustrated in FIG. 1, according to another embodiment of the present invention;

FIG. 7 is a diagram for describing a method of forming solar cell strings of the solar cell module of the embodiment illustrated in FIG. 1, according to another embodiment of the present invention;

FIG. 8 is a diagram for describing a method of forming solar cell strings of the solar cell module of the embodiment illustrated in FIG. 1, according to yet another embodiment of the present invention; and

FIG. 9 is a cross-sectional view taken along the line III-III′ illustrated in FIG. 8.

### DETAILED DESCRIPTION

Reference will now be made in detail to embodiments of the present invention, examples of which are illustrated in the accompanying drawings, wherein like reference numerals refer to like elements throughout. In this regard, the embodiments of the present invention may have different forms, and should not be construed as being limited to the descriptions set forth herein. Accordingly, the embodiments are merely described below, by referring to the figures, to explain aspects of the present description.

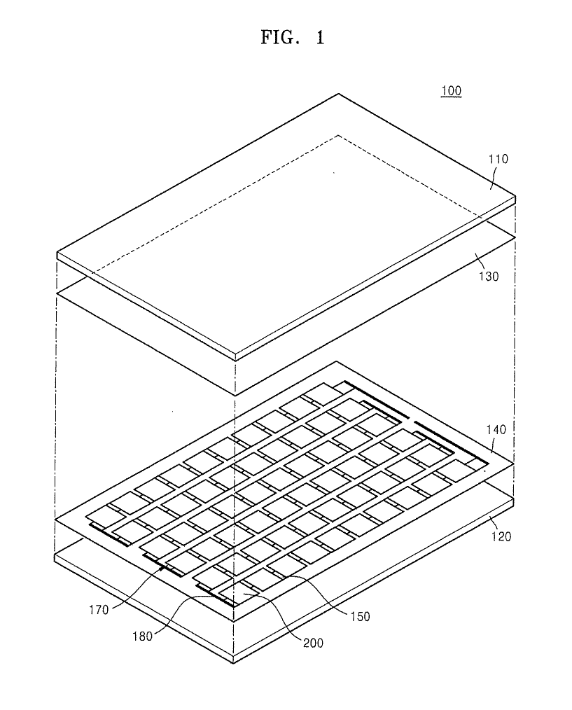

FIG. 1 is an exploded perspective view of a solar cell module 100 according to an embodiment of the present invention. Referring to FIG. 1, the solar cell module 100 may include a plurality of solar cells 200, conductive patterns 150 for electrically coupling the solar cells 200 to form solar cell strings 170, a first sealing film 130 and a front substrate 110 located on the solar cell strings 170, and a second sealing film 140 and a back substrate 120 located under the solar cell strings 170.

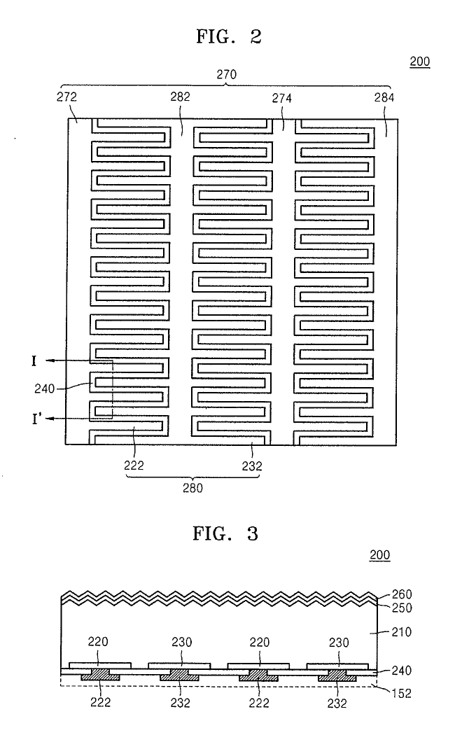

Each of the solar cells 200 may be a semiconductor element for transforming solar energy into electric energy, and may include a light receiving surface on which sunlight is incident, and an opposite surface that is opposite to the light receiving surface. The solar cells 200 may be, for example, silicon solar cells, compound semiconductor solar cells, dye-sensitized solar cells, or tandem solar cells. The solar cells 200 will be described in detail below with reference to FIGS. 2 and 3.

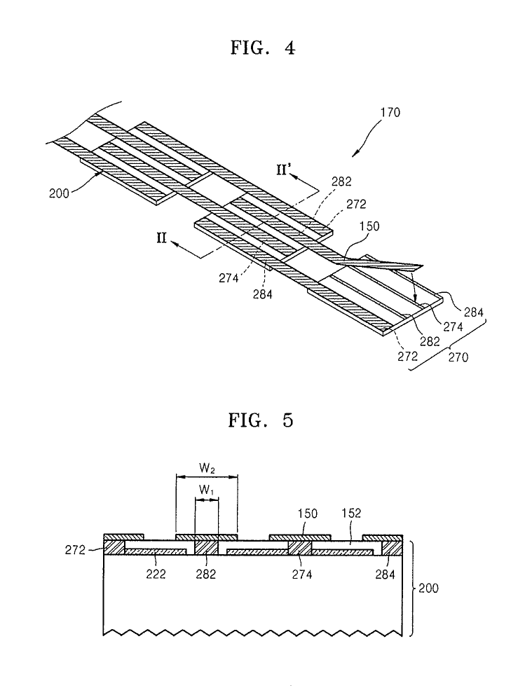

The conductive patterns 150 may electrically couple the solar cells 200 in series, in parallel, or partly in series and partly in parallel. A width of the conductive patterns 150 may be greater than the width of bus bars 270 (see FIGS. 2 and 3) formed on the solar cells 200 and bonded to the conductive patterns 150 to electrically couple the solar cells 200. As such, a series resistance generated when the solar cells 200 are coupled may be reduced or minimized, required alignment accuracy between the solar cells 200 and the conductive patterns 150 may be lowered, and thus a manufacturing yield of the solar cell module 100 may be increased. Detailed descriptions thereof will be provided below with reference to FIGS. 4 and 5.

The solar cells 200 electrically coupled by the conductive patterns 150 may form the solar cell strings 170, and the solar cell strings 170 may be adjacent to each other to form a plurality of columns. In FIG. 1, the conductive patterns 150 couple the solar cells 200 in lines so as to form six strings 170 and each of the strings 170 includes ten solar cells 200. However, the current embodiment is not limited thereto and may be variously modified.

Also, the solar cell strings 170 may be electrically coupled by bus ribbons 180. In more detail, the bus ribbons 180 may be in rows at two ends of the solar cell strings 170 that extend in columns, and may alternately couple two ends of the conductive patterns 150 of the solar cell strings 170. Also, the bus ribbons 180 may be electrically coupled to a junction box (not shown) located on a back surface of the solar cell module 100.

The first sealing film 130 is located on the light receiving surfaces of the solar cells 200, and the second sealing film 140 is located on the opposite surfaces of the solar cells 200. The first and second sealing films 130 and 140 are bonded by using a lamination process, and block or reduce the presence of moisture or oxygen that may negatively influence the solar cells 200.

The first and second sealing films 130 and 140 may be formed of, for example, ethylene vinyl acetate copolymer resin (EVA), polyvinyl butyral (PVB), silicon resin, ester-based resin, or olefin-based resin.

The front substrate 110 may be located on the first sealing film 130 and may be formed of, for example, a glass or polymer material having an excellent light transmittance. Also, to protect the solar cells 200 from an external impact, the front substrate 110 may be formed of tempered glass. To reduce or prevent the reflection of, and to increase the transmittance of, sunlight, the front substrate 110 may be formed of low-iron tempered glass.

The back substrate 120 may protect the solar cells 200 on the opposite surfaces of the solar cells 200, may have waterproofing/water-resistive properties, insulating functions, and ultraviolet blocking functions, and may be, for example, a Tedlar/PET/Tedlar (TPT) type. Also, the back substrate 120 may be formed of a material having an excellent reflectance so as to reflect sunlight transmitted to the back substrate 120 toward the front substrate 110, thus reusing, or recapturing, the sunlight. Alternatively, the back substrate 120 may be formed of a transparent material through which sunlight is incident, such that a bifacial solar cell module may be implemented.

The solar cell module 100 may generate direct-current power, and the generated direct-current power may be provided to the junction box electrically coupled to the bus ribbons 180. The junction box may be located on the back substrate 120 of the solar cell module 100, and may include circuit elements such as, for example, a capacitor unit for charging and discharging electric energy generated by the solar cells 200, and a diode for reducing or preventing electricity from flowing backward. To protect the circuit elements, the junction box may be internally coated to reduce or prevent penetration of moisture. Also, an inverter unit (not shown) for transforming direct-current power provided by the solar cell module 100 into alternating-current power, and for outputting the alternating-current power, may be included so as to implement a solar power system.

FIG. 2 is a diagram showing a solar cell 200 of the solar cell module 100 of the embodiment illustrated in FIG. 1, according to an embodiment of the present invention. FIG. 3 is a cross-sectional view taken along the line I-I′ illustrated in FIG. 2. For convenience of explanation, FIG. 2 shows a back surface of the solar cell 200, and does not illustrate an insulating layer 152 (see FIG. 5).

Referring to FIGS. 2 and 3, the solar cell 200 may be a back-contact solar cell, and may include a substrate 210 formed of a semiconductor having a first conductive type, an emitter diffusion region 220 formed on a back surface of the substrate 210, a back surface field region 230 formed on the back surface of the substrate 210, bus bars 270 formed on the back surface of the substrate 210, and finger lines (e.g., protrusions) 280 coupled to the bus bars 270. The solar cell 200 may further include a front surface field layer 250 and an anti-reflective layer 260 formed on a front surface of the substrate 210.

Initially, as a light absorption layer, the substrate 210 may be formed of monocrystalline silicon and/or polycrystalline silicon, and may be doped with an impurity to have the first conductive type. For example, the substrate 210 may be doped with an N-type impurity (e.g., a group V element such as phosphorus (P), arsenic (As), or antimony (Sb)) so as to have an N type. Otherwise, the substrate 210 may be doped with a P-type impurity (e.g., a group III element such as boron (B), aluminum (Al), or gallium (Ga)) so as to have a P type.

The emitter diffusion region 220 may be formed on the back surface of the substrate 210, and may have a conductive type that is opposite to the conductive type of the substrate 210. For example, if the substrate 210 has an N type, the emitter diffusion region 220 may be doped with a group III element such as boron (B), gallium (Ga), or indium (In) so as to have a P type. Otherwise, if the substrate 210 has a P type, the emitter diffusion region 220 may be doped with a group V element so as to have an N type.

The back surface field region 230 may be a highly doped region, and may reduce or prevent recombination of carriers on the back surface of the substrate 210. The back surface field region 230 may have a conductive type that is the same as the conductive type of the substrate 210.

As illustrated in FIG. 2, the solar cell 200 may include the bus bars 270 formed on the back surface of the solar cell 200, and the finger lines 280 protruding from the bus bars 270 in directions perpendicular to the bus bars 270. A thickness of the finger lines 280 is less than the thickness of the bus bars 270. The finger lines 280 collect charges generated due to a photoelectric effect, and the bus bars 270 are bonded to the conductive patterns 150 illustrated in FIG. 1 to externally transmit the charges collected by the finger lines 280.

For example, the bus bars 270 may include first through fourth bus bars 272, 282, 274, and 284 arranged in parallel and spaced apart from each other, wherein the first and third bus bars 272 and 274 are coupled to the emitter diffusion region 220, and the second and fourth bus bars 282 and 284 are coupled to the back surface field region 230.

Also, the third bus bar 274 coupled to the emitter diffusion region 220 may be located between the second and fourth bus bars 282 and 284, which are coupled to the back surface field region 230, and the second bus bar 282 coupled to the back surface field region 230 may be located between the first and third bus bars 272 and 274, which are coupled to the emitter diffusion region 220. That is, the first and third bus bars 272 and 274 coupled to the emitter diffusion region 220, and the second and fourth bus bars 282 and 284 coupled to the back surface field region 230 may be alternately arranged with each other.

The finger lines 280 protrude from the bus bars 270 in directions perpendicular to the bus bars 270. For example, first finger lines 222 coupled to the first bus bar 272 may protrude toward the second bus bar 282 adjacent to the first bus bar 272, and second finger lines 232 coupled to the second bus bar 282 may protrude toward the first and third bus bars 272 and 274 adjacent to the second bus bar 282.

Also, as illustrated in FIG. 3, since the first finger lines 222 are electrically coupled to the emitter diffusion region 220 and the second finger lines 232 are electrically coupled to the back surface field region 230, the first and second finger lines 222 and 232 may be spaced apart from each other. For example, the second finger lines 232 protruding from the second bus bar 282 toward the first bus bar 272, and the first finger lines 222 protruding from the first bus bar 272 toward the second bus bar 282, may be arranged alternately with each other.

Accordingly, since the solar cell 200 includes four bus bars 270 arranged alternately with each other, and a plurality of finger lines 280 also arranged alternately with each other, even when the substrate 210 has a size equal to or greater than 5 inches, a reduction in efficiency due to an increase in paths of carriers for collecting charges may be reduced or prevented. Also, unlike the embodiment illustrated in FIG. 2, six or more bus bars 270 may be included in other embodiments of the present invention. A passivation layer 240 may reduce or minimize the loss of charges, and may be formed as, for example, a silicon oxide (SiOx) layer or a silicon nitride (SiNx) layer. The bus bars 270 and the finger lines 280 may be electrically coupled to the emitter diffusion region 220 or the back surface field region 230 via holes formed in the passivation layer 240.

The solar cell 200 may further include the insulating layer 152. As will be described below with reference to FIGS. 4 and 5, the insulating layer 152 may prevent (or reduce the prominence of) steps that may be formed when the conductive patterns 150 having a width greater than the width of the bus bars 270 are coupled to the bus bars 270, and may reduce or prevent shorts between the finger lines 280 having different conductive types.

Also, an upper surface of the substrate 210 may be textured to include an uneven structure, and the solar cell 200 may include the front surface field layer 250 and the anti-reflective layer 260 formed on the upper surface of the substrate 210.

Here, texturing refers to forming an uneven pattern on a surface. If a surface becomes rough and uneven, the reflectance of incident light is reduced, and thus the amount of captured light is increased. Accordingly, an optical loss may be reduced. Also, if the substrate 210 has a textured surface, the front surface field layer 250 and the anti-reflective layer 260 sequentially formed on the substrate 210 may also be formed according to the uneven structure of the textured front surface of the substrate 210.

The front surface field layer 250 is a highly doped layer that reduces or prevents recombination of carriers on the upper surface of the substrate 210. The front surface field layer 250 may be formed of, for example, amorphous silicon (a-Si) or SiNx doped with an impurity.

The anti-reflective layer 260 reduces the reflectance of sunlight incident on the front surface of the substrate 210. For example, the anti-reflective layer 260 may be formed of silicon oxide (SiOx), silicon nitride (SiNx), or silicon oxinitride (SiOxNy), and may be formed as a single layer or may be formed as a plurality of layers.

FIG. 4 is a diagram for describing a method of forming the solar cell strings 170 of the solar cell module 100 of the embodiment illustrated in FIG. 1, according to an embodiment of the present invention. FIG. 5 is a cross-sectional view taken along the line II-II′ illustrated in FIG. 4.

Initially, referring to FIG. 4, the conductive patterns 150 electrically couple the solar cells 200. Although four bus bars 270 are illustrated in the embodiment shown in FIG. 4, different numbers of bus bars 270 may be included in other embodiments of the present invention.

As illustrated in FIG. 4, the conductive patterns 150 may couple the solar cells 200 in series by respectively coupling the first and third bus bars 272 and 274 of an arbitrary solar cell 200 to the fourth and second bus bars 284 and 282 of a neighboring solar cell 200 of the arbitrary solar cell 200.

In the present embodiment, neighboring solar cells 200 may be arranged in a 180°-rotated state with respect to each other. That is, the first through fourth bus bars 272, 282, 274, and 284 of two neighboring solar cells 200 may be arranged in opposite orders (e.g., first and third bus bars 272 and 274 may be arranged in a direction that is opposite to that of the second and fourth bus bars 282 and 284), and neighboring solar cells 200 may be electrically coupled in series, and a required length of the conductive patterns 150 may be reduced or minimized.

For example, the conductive pattern 150 and the third bus bar 274 may be bonded by using a tabbing process. The tabbing process may be performed by coating flux (not shown) on the third bus bar 274, disposing the conductive pattern 150 on the third bus bar 274 coated with the flux, and performing a baking process.

Alternatively, a conductive film (not shown) may be adhered between the conductive pattern 150 and the third bus bar 274, and then the conductive pattern 150 and the third bus bar 274 may be bonded by using a thermo-compression process. The conductive film may be a polymer film in which conductive particles are dispersed. The conductive particles may be exposed outside the film due to the thermo-compression process, and the third bus bar 274 and the conductive pattern 150 may be electrically coupled due to the exposed conductive particles.

The conductive particles may be gold (Au), silver (Ag), nickel (Ni), or copper (Cu) particles having an excellent conductivity, or may be particles obtained by plating polymer particles with the above-mentioned metals. If the solar cells 200 are coupled and modularized by using the conductive film, a process temperature may be lowered, and thus the solar cell strings 170 may be less likely to warp, or may be prevented from being warped altogether.

The conductive patterns 150 are formed in parallel along a length direction of the bus bars 270, overlap with the bus bars 270, and have a width W2 greater than a width W1 of the bus bars 270, as illustrated in FIG. 5.

If the width W2 of the conductive patterns 150 is greater than the width W1 of the bus bars 270, a series resistance generated when the solar cells 200 are electrically coupled may be reduced or minimized while maintaining connection characteristics between the bus bars 270 and the conductive patterns 150. Also, required alignment accuracy between the bus bars 270 and the conductive patterns 150 may be lowered, and thus a manufacturing yield of the solar cell module 100 may be increased.

In addition, if the width W2 of the conductive patterns 150 is relatively greater than the width W1 of the bus bars 270, since a series resistance generated when the solar cells 200 are electrically coupled is reduced or minimized, the thickness of the bus bars 270 as well as the thickness of the conductive patterns 150 may be reduced, and thus substrate bowing caused by conventional thick bus bars may be reduced or prevented. Accordingly, when the solar cells 200 each including the substrate 210 having a small thickness are modularized, breakage of the solar cells 200 may be reduced, and thus a manufacturing yield of the solar cell module 100 may be increased.

A ratio W2/W1 of the width W2 of the conductive patterns 150 to the width W1 of the bus bars 270 may be greater than 1 and less than 50. If the ratio W2/W1 is equal to or less than 1, the thicknesses of the conductive patterns 150 and the bus bars 270 may have to be increased to reduce a series resistance. However, if the thickness of the conductive patterns 150 is increased, the solar cells 200 may be broken in a lamination process for manufacturing the solar cell module 100. If the thickness of the bus bars 270 is increased, substrate bowing may occur, and thus the solar cells 200 may be broken. Otherwise, if the ratio W2/W1 is equal to or greater than 50, a short may occur between neighboring conductive patterns 150. To reduce the likelihood of a short between neighboring conductive patterns 150, the distance between neighboring conductive patterns 150 may be equal to or greater than at least 2 mm.

However, the width W2 of the conductive patterns 150, the width W1 of the bus bars 270, and the distance between neighboring conductive patterns 150 may be variously set according to the size of the solar cells 200, the number of the bus bars 270, and the distance between the bus bars 270.

Referring back to FIG. 5, the solar cell 200 may include the insulating layer 152 located between the first through fourth bus bars 272, 282, 274, and 284. The insulating layer 152 may be formed of, for example, polyimide, polyamide-imide, or silicon.

The insulating layer 152 may have a thickness that is the same as the thickness of the bus bars 270, and may cover the first finger lines 222 having a thickness that is less than the thickness of the bus bars 270. As such, a short between the first finger lines 222 and the conductive patterns 150 having different conductive types may be less likely, or may be prevented altogether.

Also, if the insulating layer 152 has a thickness that is the same as the thickness of the bus bars 270, since the conductive patterns 150 having a width greater than the width of the bus bars 270 do not result in the formation of steps when bonded to the bus bars 270, and since the conductive patterns 150 are coupled to the bus bars 270 and portions of the insulating layer 152 formed outside the bus bars 270, a bonding force of the conductive patterns 150 may be improved.

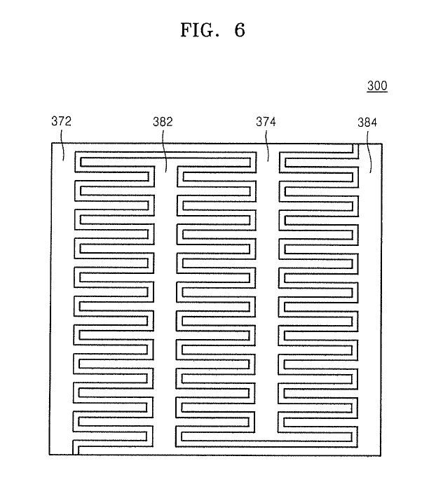

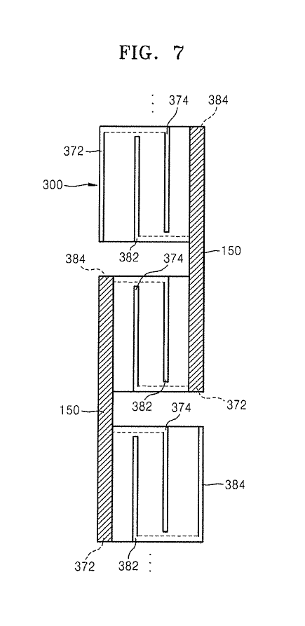

FIG. 6 is a plan view of solar cells 300 of the solar cell module 100 of the embodiment illustrated in FIG. 1, according to another embodiment of the present invention. FIG. 7 is a diagram for describing a method of forming solar cell strings of the solar cell module 100 of the embodiment illustrated in FIG. 1, according to another embodiment of the present invention.

Like FIG. 2, FIG. 6 shows a back surface of the solar cell 300 and does not illustrate an insulating layer. However, the insulating layer 152 illustrated in FIG. 5 may also be applied to the solar cell 300. Also, since the solar cell 300 has a structure similar to the structure of the solar cell 200 of the embodiment illustrated in FIG. 2, repeated descriptions will not be provided, and only differences will be described here.

FIG. 6 shows that first and third bus bars 372 and 374 of the solar cell 300 may be electrically coupled, and second and fourth bus bars 382 and 384 of the solar cell 300 may be electrically coupled. The first and third bus bars 372 and 374 or the second and fourth bus bars 382 and 384 may be electrically coupled by using any appropriate method. For example, the first bus bar 372 may extend to, and thus may be coupled to the third bus bar 374.

As illustrated in FIG. 7, the conductive patterns 150 electrically couple the solar cells 300 by using a tabbing process or a conductive film (not shown). However, since the first and third bus bars 372 and 374 are electrically coupled to each other and the second and fourth bus bars 382 and 384 are electrically coupled to each other, the conductive patterns 150 may electrically couple the solar cells 300 in series by electrically coupling the first bus bar 372 included in an arbitrary solar cell 300 to the fourth bus bar 384 included in a neighboring solar cell 300 of the arbitrary solar cell 300.

In this case, the first through fourth bus bars 372, 382, 374, and 384 of two neighboring solar cells 300 may be arranged in opposite orders. That is, as in FIG. 4, neighboring solar cells 300 may be arranged in a 180°-rotated state with respect to each other, and thus may be more easily coupled.

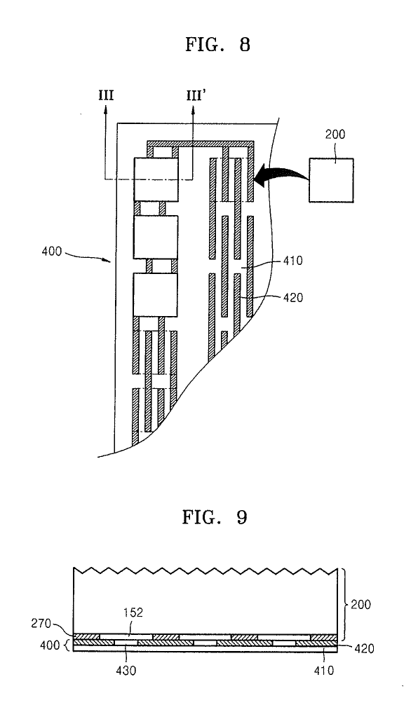

FIG. 8 is a diagram for describing a method of forming solar cell strings of the solar cell module 100 of the embodiment illustrated in FIG. 1, according to another embodiment of the present invention. FIG. 9 is a cross-sectional view taken along the line III-III′ illustrated in FIG. 8.

In FIG. 8, the solar cells 200 illustrated in FIG. 2 are electrically coupled by using a printed wiring board (PWB) 400. However, the PWB 400 of the present embodiment is not limited thereto, and may also have printed wirings for electrically coupling the solar cells 300 of the embodiment illustrated in FIG. 6.

The PWB 400 may include an insulating film 410 and conductive patterns 420 printed on the insulating film 410.

The insulating film 410 may be formed of, for example, a polymer such as polyethylene terephthalate (PET) or polyethylene naphthalate (PEN).

The conductive patterns 420 may be formed on the insulating film 410. For example, the conductive patterns 420 may be formed by printing metal such as gold (Au), silver (Ag), aluminum (Al), or titanium (Ti) on the insulating film 410 by using a screen printing, inkjet printing, or gravure printing method, or by laminating a metal sheet on the insulating film 410 and then removing portions other than the conductive patterns 420.

The solar cells 200 may be bonded onto the PWB 400 so as to be electrically coupled to each other.

Referring to FIG. 9, when the solar cell 200 is attached (e.g., bonded) onto the PWB 400, since the bus bars 270 and the conductive patterns 420 of the solar cell 200 are directly coupled, excellent electrical characteristics may be obtained.

In this case, a width of the conductive patterns 420 may be greater than the width of the bus bars 270, and a ratio of the width of the conductive patterns 420 to the width of the bus bars 270 may be greater than 1 and less than 50.

An adhesive layer 430 may be formed between the conductive patterns 420. The adhesive layer 430 prevents (or reduces the likelihood of) a short between the conductive patterns 420 and reduces the likelihood of the solar cell 200 from being detached or departed in a modularization process.

If the solar cells 200 are located on the PWB 400 and are then modularized as described above, the solar cell module 100 further includes the insulating film 410 between the solar cells 200 and the second sealing film 140.

As described above, according to one or more of the above embodiments of the present invention, since a width of conductive patterns is greater than the width of bus bars, a resistance generated when a plurality of solar cells are electrically coupled by the conductive patterns may be reduced or minimized, and thus a reduction in output of a solar cell module may also be reduced or minimized.

Also, since a width of conductive patterns is greater than the width of bus bars, the necessary alignment accuracy between solar cells and the conductive patterns may be lowered, and thus a manufacturing yield may be increased.

The present invention is not limited to the above-described embodiments and parts or the whole embodiments may be selectively combined to achieve various modifications thereof.

It should be understood that the exemplary embodiments described herein should be considered in a descriptive sense only, not for purposes of limitation. Descriptions of features or aspects within each embodiment should typically be considered as available for other similar features or aspects in other embodiments.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and their equivalents.

What is claimed is:

1. A solar cell module comprising:
solar cell strings comprising:
a plurality of solar cells; and
conductive patterns for electrically coupling respective ones of the plurality of solar cells to each other;
a first sealing film and a front substrate on the solar cell strings; and
a second sealing film and a back substrate under the solar cell strings,
wherein each of the plurality of solar cells comprises:
bus bars on a back surface of a respective one of the solar cells;
a plurality of finger lines protruding from the bus bars in a direction substantially perpendicular to the bus bars; and
an insulating layer for covering the plurality of finger lines,
wherein the conductive patterns are arranged in parallel along a length direction of the bus bars, overlap with the bus bars, and have a width greater than the a width of the bus bars.

2. The solar cell module of claim 1, wherein portions of the conductive patterns are on the insulating layer.

3. The solar cell module of claim 1, wherein each of the plurality of solar cells comprises:
a substrate comprising a silicon semiconductor having a first conductive type;
an emitter diffusion region on a back surface of the substrate and having a second conductive type opposite to the first conductive type; and
a back surface field region on the back surface of the substrate and having the first conductive type.

4. The solar cell module of claim 3, wherein an upper surface of the substrate comprises an uneven structure.

5. The solar cell module of claim 3, further comprising a front surface field layer and an anti-reflective layer on an upper surface of the substrate.

6. The solar cell module of claim 3, wherein the bus bars comprise first through fourth bus bars arranged in parallel and spaced apart from each other,
wherein the first and third bus bars are electrically coupled to the emitter diffusion region, and
wherein the second and fourth bus bars are electrically coupled to the back surface field region.

7. The solar cell module of claim 6, wherein the third bus bar is between the second and fourth bus bars, and
wherein the second bus bar is between the first and third bus bars.

8. The solar cell module of claim 6, wherein the insulating layer is between the bus bars.

9. The solar cell module of claim 6, wherein the first and third bus bars are electrically coupled to each other, and
wherein the second and fourth bus bars are electrically coupled to each other.

10. The solar cell module of claim 9, wherein the conductive patterns are on the first and fourth bus bars.

11. The solar cell module of claim 1, wherein the conductive patterns comprise metal.

12. The solar cell module of claim 11, further comprising a conductive film between the conductive patterns and the bus bars.

13. The solar cell module of claim 1, further comprising an insulating film between at least one of the solar cells and the second sealing film.

14. The solar cell module of claim 13, wherein the conductive patterns are on the insulating film.

15. A solar cell module comprising solar cell strings comprising a plurality of solar cells electrically coupled by conductive patterns,
wherein each of the solar cells comprises:
bus bars on a back surface of a respective one of the solar cells;
a plurality of finger lines protruding from the bus bars in a direction substantially perpendicular to the bus bars; and
an insulating layer for covering the plurality of finger lines and being level with the bus bars, and
wherein the conductive patterns are arranged in parallel along a length direction of the bus bars and are coupled to the bus bars and portions of the insulating layer outside the bus bars.

16. The solar cell module of claim 15, wherein each of the plurality of solar cells comprises:
a substrate comprising a silicon semiconductor; and
an emitter diffusion region and a back surface field region on a back surface of the substrate,
wherein the emitter diffusion region and the back surface field region have opposite conductive types,
wherein the bus bars comprise first through fourth bus bars arranged in parallel and spaced apart from each other, and
wherein the first and third bus bars are electrically coupled to the emitter diffusion region,
wherein the second and fourth bus bars are electrically coupled to the back surface field region, and wherein the first and third bus bars are arranged alternately with the second and fourth bus bars.

17. The solar cell module of claim 16, wherein the conductive patterns respectively electrically couple the first and third bus bars of one of the solar cells to the fourth and second bus bars of a neighboring one of the solar cells.

18. The solar cell module of claim 16, wherein the first and third bus bars are electrically coupled to each other, and
wherein the second and fourth bus bars are electrically coupled to each other.

19. The solar cell module of claim 18, wherein the conductive patterns electrically couple the first bus bar of one of the solar cells to the fourth bus bar in a neighboring one of the solar cells.

20. The solar cell module of claim 15, wherein a ratio of a width of the conductive patterns to a width of the bus bars is greater than 1 and less than 50.
